(19) United States
(12) Patent Application Publication
(10) Pub. No.: US 2016/0195890 A1
(43) Pub. Date: Jul. 7, 2016

(54) CONSTANT-CURRENT CIRCUIT AND SENSOR DEVICE HAVING THIS

(71) Applicant: ALPS ELECTRIC CO., LTD., Tokyo (JP)

(72) Inventors: Akira Asao, Miyagi-ken (JP); Kiyoshi Sasai, Miyagi-ken (JP)

(21) Appl. No.: 14/976,946

(22) Filed: Dec. 21, 2015

(30) Foreign Application Priority Data
Jan. 5, 2015 (JP) 2015-000143

(51) Int. Cl. G05F 3/26; G01R 17/00

(52) U.S. Cl. CPC G05F 3/267; G01R 17/00

(57) ABSTRACT

A first transistor and a second transistor form a current mirror circuit. A second current flowing in the second transistor is kept constant by a current control circuit. Therefore, a first current, to be output to a load, in the first transistor is kept at a constant value responsive to the second current in the second transistor. Since a drain voltage in the second transistor is controlled so as to become equal to a drain voltage in the first transistor, even if a voltage at an output terminal changes in response to a change in the impedance of the load, a ratio between the first current and the second current becomes substantially equal to a size ratio K between the first transistor and the second transistor. That is, the first current and second current precisely operate as a current mirror circuit.

This application claims benefit of priority to Japanese Patent Application No. 2015-000143 filed on Jan. 5, 2015, which is hereby incorporated by reference.

### BACKGROUND

1. Field of the Disclosure

The present disclosure relates to a constant-current circuit that supplies a constant current to a load and also relates to a sensor device that includes the constant-current circuit.

2. Description of the Related Art

A circuit that uses a current mirror circuit to supply a constant current to a load is generally known. In an ordinary current mirror circuit, a difference occurs between a voltage in one transistor in which a load current flows (when the transistor is a metal-oxide semiconductor (MOS) transistor, the voltage is a drain-source voltage) and a voltage in another transistor in which a constant current flows, so the load current changes in response to this difference in voltage. In view of this, when high constant-current performance is required, cascode transistors are generally added.

FIG. 3 illustrates an example of a conventional constant-current circuit in which cascode transistors are provided. The constant-current circuit in FIG. 3 includes p-channel metal-oxide semiconductor (PMOS) transistors M11 to M14 and a constant-current source CS1. The transistors M11 and M12 form a current mirror circuit. The sources of the transistors M11 and M12 are connected to a power supply voltage VDD terminal and their gates are connected in common to the drain of the transistor M12. The transistor M13 forms a cascode circuit together with the transistor M11. The source of the transistor M13 is connected to the drain of the transistor M11, and the drain of the transistor M13 is connected to ground through a load RL. The transistor M14 generates a bias voltage Vg to be supplied to the gate of the transistor M13. The source of the transistor of the M14 is connected to the drain of the transistor M12, and the gate and drain of the transistor M14 are connected to ground through the constant-current source CS1. The bias voltage Vg generated at the gate of the transistor M14 is input to the gate of the transistor M13.

In the constant-current circuit illustrated in FIG. 3, the bias voltage Vg to be input to the gate of the transistor M13 is a substantially constant voltage that is determined according to the value of a current in the constant-current source CS1 and to threshold voltages for the transistors M12 and M14. The drain voltage Vd in the transistor M11 is higher than the bias voltage Vg by the gate-source voltage Vgs in the transistor M13. When the Impedance of the load RL changes, a drain voltage Vo in the transistor M13 also changes accordingly. When compared with this change in voltage, the change in the gate-source voltage Vgs is adequately small. Therefore, even if the impedance of the load RL changes, a change in the drain voltage Vd in the transistor M11 is suppressed to a small value. When the drain voltage Vd in the transistor M11 becomes substantially constant, the drain current in the transistor M11 becomes substantially constant, so constant-current performance is improved.

In the constant-current circuit illustrated in FIG. 3, two transistors (M11 and M13) are provided between the output terminal To for a load current and the power supply voltage terminal VDD. Therefore, the upper limit of an output voltage range is restricted to a voltage lower than the power supply voltage VDD by a voltage equivalent to an overdrive voltage for two transistors (M12 and M14). When the output voltage range is restricted, if the impedance of the load RL is the same, the range of currents that can be supplied to the load RL is restricted. In an application in which more currents are required, a wide output voltage range is desirable. If, for example, a constant current is supplied from a constant-current circuit to a bridge circuit including resistive sensor elements used in piezoelectric sensors or the like, the larger a supplied current is, the larger the amplitude of an output signal from the bridge circuit is, improving a signal-to-noise (SN) ratio. Therefore, it is preferable for the output voltage range of a constant-current circuit to be as wide as possible.

### SUMMARY

A constant-current circuit according to a first aspect of the present invention includes a first transistor in which a first current to be output to a load flows, a second transistor that forms a current mirror circuit together with the first transistor, a current control circuit that keeps a second current constant, the second current flowing in the second transistor, and a voltage control circuit that controls a voltage that is generated in the second transistor in response to the second current so that the voltage becomes equal to a voltage that is generated in the first transistor in response to the first current.

In the above structure, the first transistor and second transistor form a current mirror circuit, and the second current flowing in the second transistor is kept constant by the current control circuit. Therefore, the first current, to be output to a load, in the first transistor is kept at a constant value responsive to the second current in the second transistor. Since the voltage generated in the second transistor is controlled so as to become equal to the voltage generated in the first transistor, even if the voltage generated in the first transistor changes in response to, for example, a change in the impedance of the load, the first current is easily kept at a constant value responsive to the second current.

### BRIEF DESCRIPTION OF THE DRAWINGS

FIG. 1 illustrates an example of the structure of a constant-current circuit according to a first embodiment;

FIG. 2 illustrates an example of the structure of a sensor device according to a second embodiment; and

FIG. 3 illustrates an example of a conventional constant-current circuit in which cascode transistors are provided.

### DESCRIPTION OF THE EXEMPLARY EMBODIMENTS

### First Embodiment

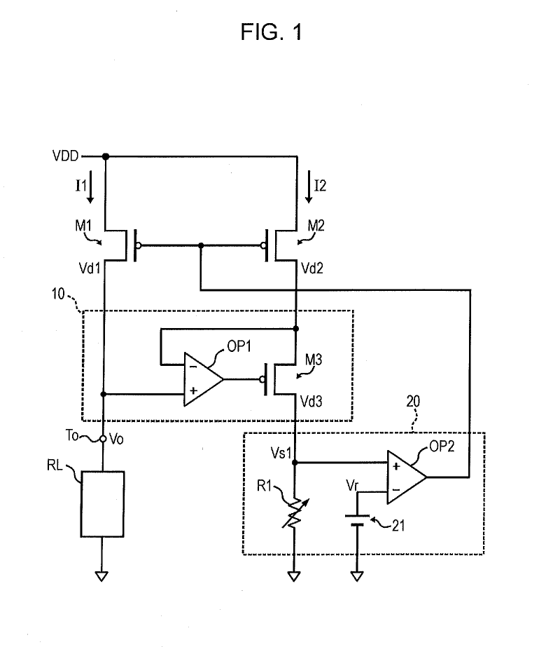

FIG. 1 illustrates an example of the structure of a constant-current circuit according to a first embodiment.

The constant-current circuit in FIG. 1 includes a first transistor M1 and a second transistor M2, which are of a PMOS type, a voltage control circuit 10, and a current control circuit 20.

The first transistor M1 and second transistor M2 form a current mirror circuit. The source of the first transistor M1 and the source of the second transistor M2 are mutually connected, and the gate of the first transistor M1 and the gate of the second transistor M2 are mutually connected. The source of the first transistor M1 and the source of the second transistor M2 are connected to a power supply voltage terminal VDD. A control signal is input from the current control circuit 20, which will be described later, to the gate of the first transistor M1 and the gate of the second transistor M2.

The drain of the first transistor M1 is connected to an output terminal To for a current. A load RL is connected between the output terminal To and ground. A first current I1 flowing in the first transistor M1 is output from the output terminal To to the load RL.

The current control circuit 20 controls a second current I2 flowing in the second transistor M2 so that the second current I2 is kept constant. In the example in FIG. 1, the current control circuit 20 includes a resistor R1, a second amplifying circuit OP2, and a reference voltage generating circuit 21.

The resistor R1 is provided in a current flow path of the second current I2. A terminal at one end of the resistor R1 is connected to ground and a terminal at the other end is connected to the drain of the second transistor M2 through the voltage control circuit 10, which will be described later. The resistor R1 is, for example, a variable resistor. By adjusting its resistance, the current value of the first current I1 can be set to a desired value.

The second amplifying circuit OP2 amplifies a difference between a reference voltage Vr and a voltage Vs1 generated across the resistor R1 in response to the second current I2, and inputs a control signal responsive to a result of amplification by the second amplifying circuit OP2 to the gate of the first transistor M1 and the gate of the second transistor M2. The second amplifying circuit OP2 is, for example, an operational amplifier. It accepts the voltage Vs1 generated across the resistor R1 at a non-inverted input terminal and accepts the reference voltage Vr at an inverted input terminal.

The voltage control circuit 10 controls a voltage that is generated between the drain and source of the second transistor M2 in response to the second current I2 so that the voltage becomes equal to a voltage that is generated between the drain and source of the first transistor M1 in response to the first current I1. That is, the voltage control circuit 10 controls a drain voltage Vd2 in the second transistor M2 so as to become equal to a drain voltage Vd1 in the first transistor M1.

In the example in FIG. 1, the voltage control circuit 10 includes a third transistor M3 and a first amplifying circuit OP1.

The third transistor M3 is disposed in a current path between the second transistor M2 and the resistor R1. The source of the third transistor M3 is connected to the drain of the second transistor M2, and the drain of the third transistor M3 is connected to the resistor R1.

The first amplifying circuit OP1 amplifies a difference between the drain voltage Vd1 in the first transistor M1 and the drain voltage Vd2 in the second transistor M2, and inputs a control signal responsive to a result of amplification by the first amplifying circuit OP1 to the gate of the third transistor M3. The first amplifying circuit OP1 is, for example, an operational amplifier. It accepts the drain voltage Vd1 at a non-inverted input terminal and accepts the drain voltage Vd2 at an inverted input terminal.

The operation of the constant-current circuit structured as described above will be described.

If the voltage Vs1 generated across the resistor R1 in response to the second current I2 is equal to the reference voltage Vr, the current value of the second current I2 is Vr/R, R being the resistance of the resistor R1. If the second current I2 becomes larger than this current value, the voltage Vs1 generated across the resistor R1 is raised, the output voltage of the second amplifying circuit OP2 is raised, and the gate voltage of the second transistor M2 is raised, so the second current I2 changes so as to be reduced. By contrast, if the second current I2 becomes smaller than the current value Vr/R, the output voltage of the second amplifying circuit OP2 is lowered and the second current I2 changes so as to be increased. Due to this negative feedback operation, the second current I2 becomes substantially equal to the current value Vr/R.

If the drain voltage Vd2 of the second transistor M2 becomes lower than the drain voltage Vd1 of the first transistor M1, the output voltage of the first amplifying circuit OP1 is raised, the gate voltage of the third transistor M3 is raised, the drain current of the third transistor M3 is reduced, the voltage Vs1 of the resistor R1 is reduced, the output voltage of the second amplifying circuit OP2 is lowered, and the gate voltage of the second transistor M2 is lowered. When the gate voltage of the second transistor M2 is lowered, a voltage between the gate and source of the second transistor M2 is raised, so a voltage between the drain and source of the second transistor M2 is lowered and the drain voltage Vd2 changes so as to be raised. Conversely, if the drain voltage Vd2 in the second transistor M2 becomes higher than the drain voltage Vd1 in the first transistor M1, the output voltage in the first amplifying circuit OP1 is lowered, the output voltage in the second amplifying circuit OP2 is raised, and the drain voltage Vd2 changes so as to be lowered. Due to this negative feedback operation, the drain voltage Vd2 of the second transistor M2 becomes substantially equal to the drain voltage Vd1 in the first transistor M1.

An equal voltage is applied between the gate and source of the first transistor M1 and between the gate and source of the second transistor M2, and the voltage between the source and drain in the first transistor M1 and the voltage between the source and drain in the second transistor M2 are controlled so that these voltages become substantially equal to each other. Therefore, a ratio between the first current I1 and the second current I2 is substantially the same as a size ratio between the first transistor M1 and the second transistor M2. Assuming that the size of the first transistor M1 is K times the size of the second transistor M2, the first current I1 is approximately K times the second current I2. Since the second current I2 is controlled so as to become substantially equal to Vr/R, the first current I1 is substantially represented as the equation below.

I1=K×(Vr/R) (1)

As described above, in the constant-current circuit according to this embodiment, the first transistor M1 and second transistor M2 form a current mirror circuit, and the second current I2 flowing in the second transistor M2 is kept constant by the current control circuit 20. Therefore, the first current I1, to be output to the load RL, in the first transistor M1 is kept at a constant value responsive to the second current I2 in the second transistor M2.

The drain voltage Vd2 in the second transistor M2 is controlled so as to become equal to the drain voltage Vd1 in the first transistor M1. Therefore, even if a voltage Vo, which is equal to Vd1, at the output terminal To changes in response to a change in the impedance of the load RL, the ratio between the first current I1 and the second current I2 becomes substantially equal to the size ratio K between the first transistor M1 and the second transistor M2. That is, the first transistor M1 and second transistor M2 precisely operate as a current mirror circuit.

Therefore, even if the voltage Vo at the output terminal To changes, the first current I1 to be output to the load RL is precisely kept constant, so it is possible to obtain very superior constant-current characteristics.

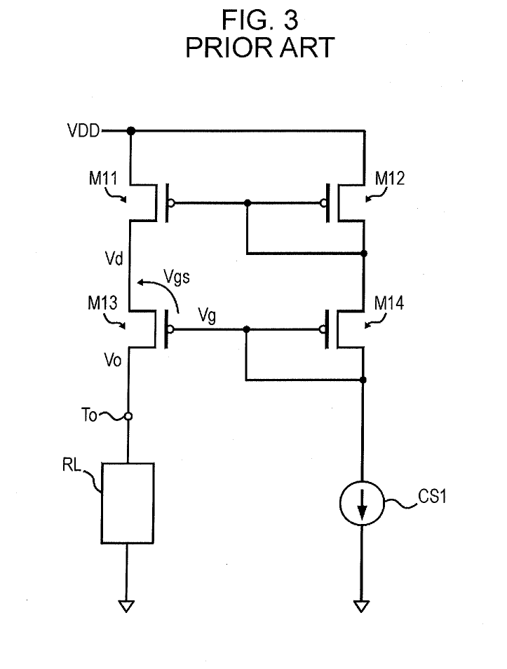

The constant-current circuit according to this embodiment operates even if only one transistor (first transistor M1) is provided in the current path to the load RL. Therefore, the range of the output voltage Vo can be widened when compared with the conventional constant-current circuit illustrated in FIG. 3.

### Second Embodiment

Next, a second embodiment of the present invention will be described.

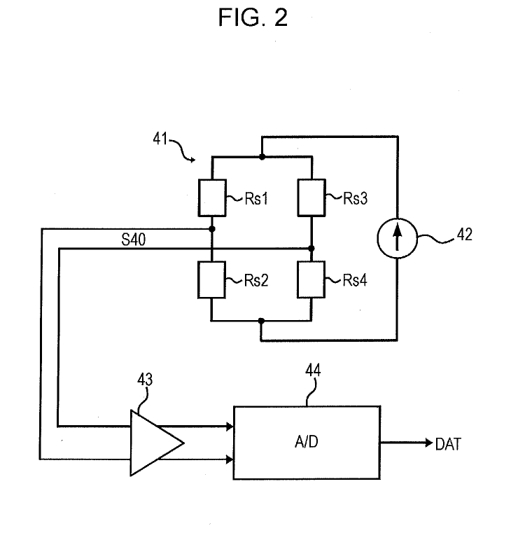

FIG. 2 illustrates an example of the structure of a sensor device according to the second embodiment. The sensor device in FIG. 2 is, for example, a pressure sensor. The sensor device includes a bridge circuit 41, a constant-current circuit 42, an amplifying circuit 43, and an analog-digital (AD) converter 44.

The bridge circuit 41 is a Wheatstone bridge circuit formed by using resistive sensor elements Rs1 to Rs4. The bridge circuit 41 outputs a detection signal S40 responsive to a change in the resistances of the resistive sensor elements Rs1 to Rs4. The resistive sensor elements Rs1 to Rs4 are each, for example, a piezoresistive element. Their resistances change depending on the pressure.

The constant-current circuit 42 supplies a constant current to the bridge circuit 41. Thus, the detection signal S40 output from the bridge circuit 41 is a voltage signal that represents a change in the resistances of the piezoresistive elements. The constant-current circuit 42 is the constant-current circuit (see FIG. 1) according to the first embodiment described above.

The amplifying circuit 43 amplifies the detection signal S40 output from the bridge circuit 41. The amplifying circuit 43 may switch an amplification gain in response to a control signal (not illustrated) for use in range switching.

The AD converter 44 converts an analog signal amplified in the amplifying circuit 43 to a digital signal and outputs the digital signal as detection data DAT.

In the sensor device according to the second embodiment, the constant-current circuit 42 has a structure illustrated in FIG. 1, so the range of voltages to be applied from the constant-current circuit 42 to the bridge circuit 41 can be widened. This enables the range of currents to be supplied to the bridge circuit 41 to be widened. Therefore, the amplitude of the detection signal S40 output from the bridge circuit 41 can be increased, so measurement precision can be improved by increasing the SN ratio.

So far, some embodiments of the present invention have been described. However, the present invention is not limited to these embodiments. The present invention includes various variations. That is, the circuit structures in the above embodiments are only examples and the circuits can be replaced with other circuits that implement similar functions.

In the constant-current circuit illustrated in FIG. 1, for example, a current mirror circuit formed by using PMOS transistors (M1 and M2) is used, but, in another embodiment of the present invention, a current mirror circuit formed by using NMOS transistors may be used.

In the constant-current circuit illustrated in FIG. 1, the third transistor M3 used in the voltage control circuit 10 is of a PMOS type, but, in another embodiment of the present invention, an NMOS transistor may be used in a voltage control circuit.

The transistors used in the constant-current circuit are not limited to MOS transistors. Transistors of other types, such as bipolar transistors, may be used.

What is claimed is:

1. A constant-current circuit comprising:
a first transistor in which a first current to be output to a load flows;
a second transistor that forms a current mirror circuit together with the first transistor;
a current control circuit that keeps a second current constant, the second current flowing in the second transistor; and
a voltage control circuit that controls a voltage that is generated in the second transistor in response to the second current so that the voltage becomes equal to a voltage that is generated in the first transistor in response to the first current.

2. The constant-current circuit according to claim 1, wherein the voltage control circuit includes:
a third transistor provided in a current path of the second current, and
a first amplifying circuit that amplifies a difference between the voltage generated in the first transistor in response to the first current and the voltage generated in the second transistor in response to the second current and inputs a signal responsive to a result of amplification by the first amplifying circuit to a control terminal provided in the third transistor.

3. The constant-current circuit according to claim 2, wherein the current control circuit includes:
a resistor provided in the current path of the second current, and
a second amplifying circuit that amplifies a difference between a voltage generated across the resistor and a predetermined reference voltage and inputs a signal responsive to a result of amplification by the second amplifying circuit to a control terminal provided in the first transistor and a control terminal provided in the second transistor.

4. The constant-current circuit according to claim 3, wherein:
the first transistor, the second transistor, and the third transistor each is a MOS transistor;
a source of the first transistor and a source of the second transistor are mutually connected;
a gate of the first transistor and a gate of the second transistor are mutually connected;
the third transistor is disposed in a current path between the second transistor and the resistor;
the first amplifying circuit amplifies a difference between a voltage at a drain of the first transistor and a voltage at a drain of the second transistor and inputs a signal responsive to a result of amplification by the first amplifying circuit to a gate of the third transistor; and
the second amplifying circuit amplifies a difference between the voltage generated across the resistor and the reference voltage and inputs a signal responsive to a result of amplification by the second amplifying circuit to the gate of the first transistor and the gate of the second transistor.

5. A sensor device comprising:
a bridge circuit comprising a resistive sensor element; and
a constant-current circuit that supplies a constant current to the bridge circuit;
wherein the constant-current circuit comprises:
a first transistor in which a first current to be output to a load flows;
a second transistor that forms a current mirror circuit together with the first transistor;
a current control circuit that keeps a second current constant, the second current flowing in the second transistor; and
a voltage control circuit that controls a voltage that is generated in the second transistor in response to the second current so that the voltage becomes equal to a voltage that is generated in the first transistor in response to the first current
